(19) United States
(12) Patent Application Publication
(10) Pub. No.: US 2014/0069692 A1
(43) Pub. Date: Mar. 13, 2014

(54) TOUCH PANEL

(71) Applicant: SAMSUNG ELECTRO-MECHANICS CO., LTD., Gyunggi-do (KR)

(72) Inventors: Jang Ho Park, Gyunggi-do (KR); Seul Gi Kim, Gyunggi-do (KR); Jin UK Lee, Gyunggi-do (KR); In Hyun Jang, Gyunggi-do (KR); Nam Keun Oh, Gyunggi-do (KR)

(73) Assignee: SAMSUNG ELECTRO-MECHANICS CO., LTD., Gyunggi-do (KR)

(21) Appl. No.: 13/688,290

(22) Filed: Nov. 29, 2012

(30) Foreign Application Priority Data
Sep. 12, 2012 (KR) 10-2012-0101004

(51) Int. Cl. H05K 1/09

(52) U.S. Cl. CPC H05K 1/09
USPC 174/250

(57) ABSTRACT

Disclosed herein is a touch panel including a transparent substrate and an electrode formed on the transparent substrate and an electrode having light transmittance of 5 to 50%, wherein as the electrode has high light transmittance, such that it is possible to solve a defective problem of visibility of the touch panel due to the opacity and specular phenomenon of the electrode.

### CROSS REFERENCE TO RELATED APPLICATION

This application claims the benefit of Korean Patent Application No. 10-2012-0101004, filed on Sep. 12, 2012, entitled “Touch Panel”, which is hereby incorporated by reference in its entirety into this application.

### BACKGROUND OF THE INVENTION

1. Technical Field

The present invention relates to a touch panel.

2. Description of the Related Art In accordance with the growth of computers using a digital technology, devices assisting computers have also been developed, and personal computers, portable transmitters and other personal information processors execute processing of text and graphics using a variety of input devices such as a keyboard and a mouse.

While the rapid advancement of an information-oriented society has widened the use of computers more and more, it is difficult to efficiently operate products using only a keyboard and a mouse currently serving as an input device. Therefore, the necessity for a device that is simple, has minimum malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of an image display device such as an electronic organizer, a flat panel display device including a liquid crystal display (LCD) device, a plasma display panel (PDP), an electroluminescence (El) element, or the like, and a cathode ray tube (CRT) to thereby be used to allow users to select desired information while viewing the image display device.

In addition, the touch panel is classified into a resistive type touch panel, a capacitive type touch panel, an electromagnetic type touch panel, a surface acoustic wave (SAW) type touch panel, and an infrared type touch panel. These various types of touch panels are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields.

In the touch panel according to the prior art, a common electrode is formed of indium tin oxide (ITO). However, the ITO has excellent electric conductivity, but since indium that is a raw material is expensive rare earth metal and is expected to be depleted within about 10 years, cannot be smoothly supplied.

For this reason, as in the touch panel described in Korean Laid-Open Publication No. 10-2010-0091497, researches for forming electrodes using metals have been actively conducted. When the electrode is formed of metal, it is advantages in that ITO has excellent electric conductivity and is smoothly supplied.

However, when the electrode of the touch panel is formed of metal, the touch panel has disadvantages in that visibility is degraded due to the opacity of the electrode and a specular phenomenon at the electrode. In order to overcome the problems, the metal electrode is blackened while implementing a fine line width of the metal electrode. In this case, there are problems in that the manufacturing process is complicated and the improvement effect in visibility is insignificant.

### SUMMARY OF THE INVENTION

The present invention has been made in effort to provide a touch panel capable of improving visibility by preventing a specular phenomenon from occurring at an electrode while securing transparency of the electrode, even when the electrode of the touch panel is formed of metal.

According to a preferred embodiment of the present invention, there is provided a touch panel including: a transparent substrate; and an electrode formed on the transparent substrate and having light transmittance of 5 to 50%.

The electrode may be formed of any one selected from copper (Cu), aluminum (Al), gold (Au), molybdenum (Ni), nickel (Ni), silver (Ag), titanium (Ti), palladium (Pd), and chromium (Cr), or an alloy thereof.

The electrode may be formed in a mesh pattern.

The electrode may have a thickness of 5 to 50 nm

The electrode may have a line width of 1 to 10 μm.

According to another preferred embodiment of the present invention, there is provided a touch panel including: a transparent substrate; a first electrode formed on one surface of the transparent substrate; an insulating layer formed on one surface of the transparent substrate; and a second electrode formed on one surface of the insulating layer, wherein any one of the first electrode and the second electrode has light transmittance of 5 to 50%.

Any one of the first electrode and the second electrode may be formed of any one selected from copper (Cu), aluminum (Al), gold (Au), molybdenum (Mo), nickel (Ni), silver (Ag), titanium (Ti), palladium (Pd), and chromium (Cr), or an alloy thereof

Any one of the first electrode and the second electrode may be formed in a mesh pattern.

Any one of the first electrode and the second electrode may have a thickness of 5 to 50 nm p Any one of the first electrode and the second electrode may have a line width of 1 to 10 μm.

According to still another preferred embodiment of the present invention, there is provided a touch panel including: a transparent substrate; a first electrode formed on one surface of the transparent substrate; and a second electrode formed on the other surface of the transparent substrate, wherein any one of the first electrode and the second electrode has light transmittance of 5 to 50%.

Any one of the first electrode and the second electrode may be formed of any one selected from copper (Cu), aluminum (Al), gold (Au), molybdenum (Mo), nickel (Ni), silver (Ag), titanium (Ti), palladium (Pd), and chromium (Cr), or an alloy thereof

Any one of the first electrode and the second electrode may be formed in a mesh pattern.

Any one of the first electrode and the second electrode may have a thickness of 5 to 50 nm

Any one of the first electrode and the second electrode may have a line width of 1 to 10 μm.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a touch panel according to a first preferred embodiment of the present invention;

FIG. 2 is an enlarged perspective view of an electrode illustrated in FIG. 1;

FIGS. 3 to 5 are experimental photographs for light transmittance of the electrode illustrated in FIG. 1;

FIG. 6 is a cross-sectional view of a touch panel according to a second preferred embodiment of the present invention; and

FIG. 7 is a cross-sectional view of a touch panel according to a third preferred embodiment of the present invention.

### DESCRIPTION OF THE PREFERRED EMBODIMENTS

The above and other objects, features and advantages of the present invention will be more clearly understood from preferred embodiments and the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, preferred embodiments of the present invention will be described in detail with reference to the accompanying drawings.

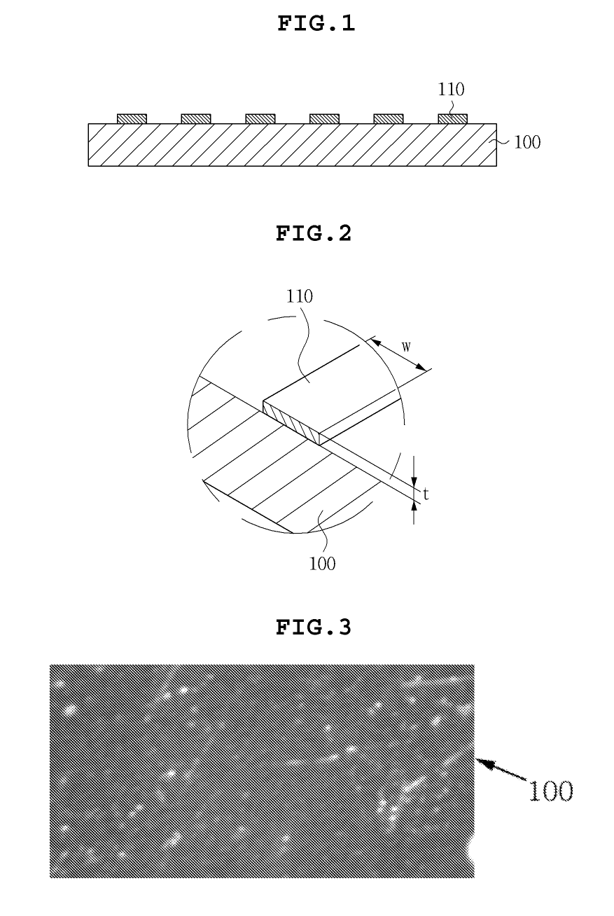

FIG. 1 is a cross-sectional view of a touch panel according to a first preferred embodiment of the present invention, FIG. 2 is an enlarged perspective view of an electrode illustrated in FIG. 1, and FIGS. 3 to 5 are experimental photographs for light transmittance of the electrode illustrated in FIG. 1.

As illustrated in FIGS. 1 and 2, a touch panel according to a first preferred embodiment of the present invention includes a transparent substrate 100 and an electrode 110. In this case, the electrode 110 has light transmittance of 5 to 50%.

The transparent substrate 100 serves to provide a region in which the electrode 110 to be described below is formed. The transparent substrate 100 needs to have support force capable of supporting the electrode 110 and transparency to allow a user to recognize images provided from an image display device.

In consideration of the support force and the transparency described above, the transparent substrate 100 may be made of polyethylene terephthalate (PET), polycarbonate (PC), poly methyl methacrylate (PMMA), polyethylene naphthalate (PEN), polyethersulpon (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), glass, or tempered glass, but is not necessarily limited thereto.

The transparent substrate 100 is preferably activated by being subjected to high frequency treatment or primer treatment. The transparent substrate 100 is treated as described above, thereby more improving adhesion between the first transparent substrate 100 and the electrode 110.

Meanwhile, the transparent substrate 100 may be a window that is provided at an outermost side of the touch panel. When the transparent substrate 100 is a window, the electrode 110 is directly formed on a window to be described below. Therefore, in the manufacturing process of the touch panel, a process of forming the electrode 110 on the separate transparent substrate 100 and then, attaching the electrode 110 to the window may be omitted, such that the overall thickness of the touch panel can be reduced.

The electrode 110 generates a signal at the time of being touched by a user, such that a controller (not illustrated) can recognize touched coordinates. The signal generated from the electrode 110 is transferred to a controller (not illustrated) through a wiring.

The electrode 110 may be formed of any one selected from copper (Cu), aluminum (Al), gold (Au), molybdenum (Mo), nickel (Ni), silver (Ag), titanium (Ti), palladium (Pd), and chromium (Cr), or an alloy thereof; in consideration of electric conductivity. Further, the electrode 110 may be formed by depositing or plating the metals on the transparent substrate 100.

The metal has more excellent electric conductivity than metal oxides such as indium tin oxide (ITO), and the like. However, the metals have an opaque characteristic due to the scattering of visible ray caused by free electrons that are present in the metal. Therefore, the electrode 110 formed of metal is generally formed to have a fine line width in consideration of the visibility of the touch panel. However, there is a limitation in the improvement in the visibility of the touch panel only by reducing the line width of the electrode 110 formed of metal.

The preferred embodiment of the present invention proposes a means for solving a defective problem of the visibility of the touch panel due to the opacity of the electrode 110 formed of metal.

In detail, the electrode 110 included in the preferred embodiment of the present invention is formed of the metals, wherein the light transmittance of the electrode 110 formed of the metals may be 5 to 50%. Further, the electrode 110 is formed of a thin film and may have the light transmittance in the above range. When the electrode 110 formed of the metals is formed of a thin film, the free electrons in the electrode 110 are reduced and thus, the light scattering or the light reflection is reduced, thereby increasing the light transmittance. Therefore, as the electrode 110 has the light transmittance in the above range, the problem of the opacity of the electrode 110 or the specular phenomenon at the surface of the electrode 110 may be sufficiently solved. Therefore, it is possible to improve the visibility of the touch panel.

In detail, as illustrated in FIG. 2, the electrode 110 may be formed to have a thin film of 5 to 50 nm.

When the electrode 110 is formed to have a thickness t within the above range, experimental examples in which the light transmittance of the electrode 110 is measured will be described with reference to FIGS. 3 to 5, together with the following experimental data.

| Light | Sheet | Cu Film | Terminal |
|---|---|---|---|
| Transmittance | Resistance | Thickness | Resistance |
| % | mΩ/ | nm | Ω |
| 23.14 | 1597 | 25 | 23955 |
| 13.19 | 1034 | 35 | 15510 |
| 4.82 | 627.2 | 50 | 9408 |
| 1.04 | 389.2 | 70 | 5838 |

<Experimental Data in which Light Transmittance According to Film Thickness of Cu is Measured>

The present experimental example corresponds to a case in which the electrode 110 is formed of copper (Cu) and shows measured values of the light transmittance, sheet resistance, and terminal resistance of the electrode 110 formed of a mesh pattern (a pattern formed of two strands of metal lines) having a width of 10 cm.

Further, FIGS. 3 to 5 are experimental photographs confirming whether a character portion is visible according to the light transmittance of the electrode 110, in the state in which the electrode 110 having a different thickness t is formed on one surface of the transparent substrate 100 and the character remains on the other surface of the transparent substrate 100 using ink.

As can be appreciated from the above experimental data, the electrode 110 has the light transmittance of about 5% or more when the electrode 110 is formed to have a thickness t of 50 nm or less.

When the light transmittance of the electrode 110 is less than 5%, the character on the other surface of the transparent substrate 100 is invisible as illustrated in FIG. 3.

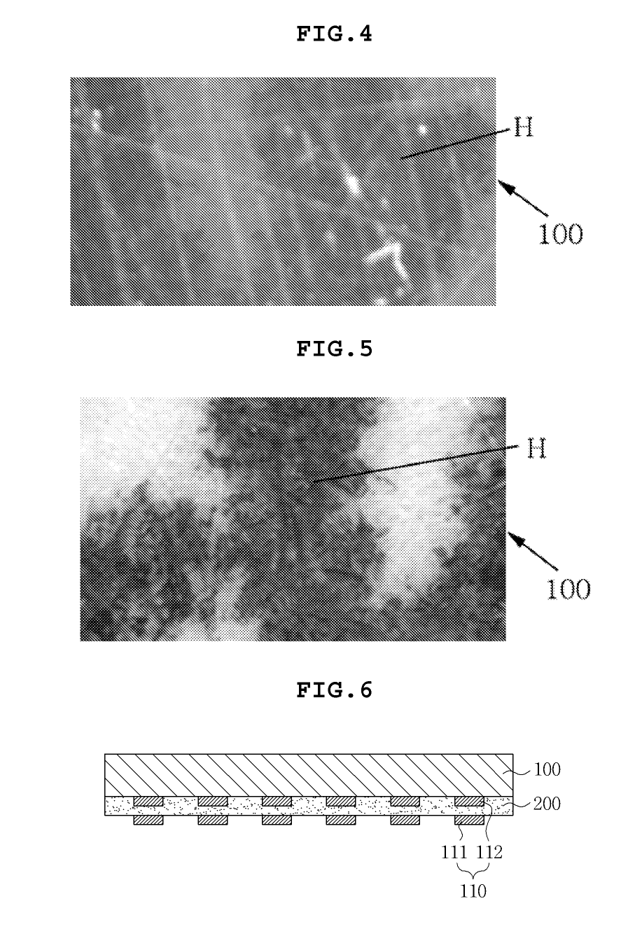

When the electrode 110 has the light transmittance of about 5% as the case in which the thickness t of the electrode 110 is formed to have about 50 nm, a character H on the other surface of the transparent substrate 100 is visible as illustrated in FIG. 4. In addition, as the thickness t of the electrode 110 is thinner than 50 nm, the light transmittance is larger and larger and as illustrated in FIG. 5, the character H on the other surface of the transparent substrate 100 is more clearly visible.

As such, as the thickness t of the electrode 110 is thin, the light transmittance is larger and larger, such that the electrode 110 is more invisible. However, there is a problem in that the thinner the thickness t of the electrode 110, the larger the resistance becomes. Therefore, the electrode 110 may be formed to have a thickness of 5 nm or more, if possible. Even though the resistance of the electrode 110 is slightly increased until the electrode 110 is formed to have a thickness t of about 5 nm, the electrode 110 maintains electric conductivity required to perform a function as the electrode 110. Comparing when the electrode 110 formed of metal is formed to have a thickness t to of about 5 nm with when the electrode 110 is formed to have a thickness of 5 nm or more, the electrode 110 has the largest light transmittance. Even though not be shown in the above experimental data and there is a slight difference according to a kind of metals forming the electrode 110, it is confirmed that the electrode 110 has the light transmittance of about 50% or more.

Meanwhile, when a line width of the electrode 110 according to the preferred embodiment of the present invention is increased out of a predetermined range, the electrode 110 may be visible from the outside despite the light transmittance of the electrode 110. Further, the resistance of the electrode 110 formed of metal has the relationship with the thickness of the electrode 110 and the line width w of the electrode 110. Therefore, the electrode 110 needs to be formed a preferable line width w so that the electrode 110 is invisible from the outside and has the required electric conductivity. Therefore, the electrode may be formed to have a line width w of 1 to 10 μm.

The foregoing electrode 110 may be divided into a driving electrode and a sensing electrode. In addition, both of the driving electrode and the sensing electrode may be formed in an active region on one surface of the transparent substrate 100.

Hereinafter, a touch panel according to a second preferred embodiment of the present invention will be described with reference to the accompanying drawings and therefore, the overlapping contents with the contents described in the first preferred embodiment will be omitted. FIG. 6 is a cross-sectional view of a touch panel according to a second preferred embodiment of the present invention.

As illustrated in FIG. 6, the touch panel according to the preferred embodiment of the present invention is configured to include the transparent substrate 100, a first electrode 111 formed on one surface of the transparent substrate 100, an insulating layer 200 formed on one surface of the transparent substrate 100, and a second electrode 112 formed on one surface of the insulating layer 200, wherein any one of the first electrode 111 and the second electrode 112 has the light transmittance of 5 to 50%.

The present preferred embodiment is different from the first preferred embodiment in that both of the driving electrode and the sensing electrode are not formed on one surface of the transparent substrate 100 but any one of the driving electrode and the sensing electrode is formed on one surface of the transparent substrate 100 and the other one thereof is formed on the insulating layer 200 to be described below that is stacked on the transparent substrate 100. Therefore, only the difference will be described in detail.

The transparent substrate 100 may be formed of a material having support force capable of supporting the electrode 110 and transparency. Further, the transparent substrate 100 may be a window that is provided on an outermost of the touch panel.

In the present preferred embodiment, the first electrode 111 is formed on one surface of the transparent substrate 100. The first electrode 111 may be controlled to serve as the driving electrode or the sensing electrode, for example, the sensing electrode.

The insulating layer 200 is stacked on one surface of the transparent substrate 100 while covering the first electrode 111. The insulating layer 200 serves to electrically insulate the first electrode 111 from the second electrode 112. Here, the insulating layer 200 may be formed of epoxy, acrylic-based resin, a SiOx thin film, a SiNx thin film, and the like. Further, the insulating layer 200 may be formed by methods, such as printing, chemical vapor deposition, sputtering, and the like.

The second electrode 112 is formed on one surface of the insulating layer 200. When the first electrode 111 is, for example, the sensing electrode, the second electrode 112 may be controlled to serve as, for example, the driving electrode.

Any one or both of the first electrode 111 and the second electrode 112 may be formed of metal like the electrode 110 described in the first preferred embodiment. In addition, the electrode may be formed in the mesh pattern. Among the first electrode 111 and the second electrode 112, the electrode formed of metal has the light transmittance of 5 to 50% like the electrode 110 according to the first preferred embodiment of the present invention and may be formed in a thin film to have the light transmittance. In detail, among the first electrode 111 and the second electrode 112, the electrode formed of metal may be formed to have a thickness of 5 to 50 nm. In addition, the electrode may be formed to have a line width of 1 to 10 μm.

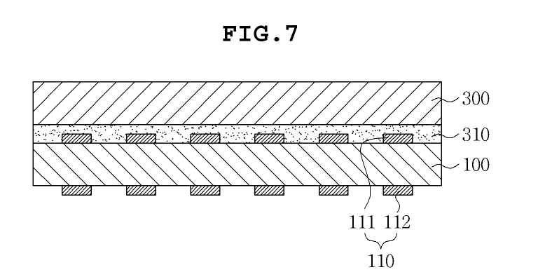

Hereinafter, a touch panel according to a third preferred embodiment of the present invention will be described with reference to the accompanying drawings. Even in the description of the third preferred embodiment of the present invention, the overlapping contents with the contents described in the first and second preferred embodiments of the present invention will be omitted. FIG. 7 is a cross-sectional view of a touch panel according to the third preferred embodiment of the present invention.

As illustrated in FIG. 7, the touch panel according to the third preferred embodiment of the present invention is configured to include the transparent substrate 100, the first electrode 111 formed on one surface of the transparent substrate 100 and the second electrode 112 formed on the other surface of the transparent substrate 100, wherein any one of the first electrode 111 and the second electrode 112 has the light transmittance of 5 to 50%.

The transparent substrate 100 included in the third preferred embodiment of the present invention may be the transparent substrate 100 that is separately attached to an adhesive layer 310 formed on a window 300. In this case, an adhesive layer 310 may be, for example, an optical clear adhesive (OCA).

Further, the first electrode 111 is formed on one surface of the transparent substrate 100 and the second electrode 112 is formed on the other surface of the transparent substrate 100.

Any one or both of the first electrode 111 and the second electrode 112 may be formed of metal like the electrode 110 described in the first preferred embodiment. In addition, the electrode may be formed in the mesh pattern. Among the first electrode 111 and the second electrode 112, the electrode formed of metal has the light transmittance of 5 to 50% like the electrode 110 according to the first preferred embodiment of the present invention and may be formed in a thin film to have the light transmittance. In detail, among the first electrode 111 and the second electrode 112, the electrode formed of metal may be formed to have a thickness of 5 to 50 nm. In addition, the electrode may be formed to have a line width of 1 to 10 μm.

According to the preferred embodiment of the present invention, the electrode formed of metal is formed of the thin film to achieve the high light transmittance, thereby preventing the electrode from being visible from the outside. Therefore, it is possible to significantly improve the visibility of the touch panel.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel, comprising:
a transparent substrate; and
an electrode formed on the transparent substrate and having light transmittance of 5 to 50%.

2. The touch panel as set forth in claim 1, wherein the electrode is formed of any one selected from copper (Cu), aluminum (Al), gold (Au), molybdenum (Ni), nickel (Ni), silver (Ag), titanium (Ti), palladium (Pd), and chromium (Cr), or an alloy thereof.

3. The touch panel as set forth in claim 1, wherein the electrode is formed in a mesh pattern.

4. The touch panel as set forth in claim 1, wherein the electrode has a thickness of 5 to 50 nm

5. The touch panel as set forth in claim 1, wherein the electrode has a line width of 1 to 10

6. A touch panel, comprising:
a transparent substrate;
a first electrode formed on one surface of the transparent substrate;
an insulating layer formed on one surface of the transparent substrate; and
a second electrode formed on one surface of the insulating layer,
wherein any one of the first electrode and the second electrode has light transmittance of 5 to 50%.

7. The touch panel as set forth in claim 6, wherein any one of the first electrode and the second electrode is formed of any one selected from copper (Cu), aluminum (Al), gold (Au), molybdenum (Mo), nickel (Ni), silver (Ag), titanium (Ti), palladium (Pd), and chromium (Cr), or an alloy thereof.

8. The touch panel as set forth in claim 6, wherein any one of the first electrode and the second electrode is formed in a mesh pattern.

9. The touch panel as set forth in claim 6, wherein any one of the first electrode and the second electrode has a thickness of 5 to 50 nm.

10. The touch panel as set forth in claim 6, wherein any one of the first electrode and the second electrode has a line width of 1 to 10 μm.

11. A touch panel, comprising:
a transparent substrate;
a first electrode formed on one surface of the transparent substrate; and
a second electrode formed on the other surface of the transparent substrate,
wherein any one of the first electrode and the second electrode has light transmittance of 5 to 50%.

12. The touch panel as set forth in claim 11, wherein any one of the first electrode and the second electrode is formed of any one selected from copper (Cu), aluminum (Al), gold (Au), molybdenum (Mo), nickel (Ni), silver (Ag), titanium (Ti), palladium (Pd), and chromium (Cr), or an alloy thereof.

13. The touch panel as set forth in claim 11, wherein any one of the first electrode and the second electrode is formed in a mesh pattern.

14. The touch panel as set forth in claim 11, wherein any one of the first electrode and the second electrode has a thickness of 5 to 50 nm.

15. The touch panel as set forth in claim 11, wherein any one of the first electrode and the second electrode has a line width of 1 to 10 μm.
